(19) United States
(12) Patent Application Publication
(10) Pub. No.: US 2019/0096673 A1
(43) Pub. Date: Mar. 28, 2019

(54) APPARATUS FOR FORMING A LAYER ON A SUBSTRATE AND METHOD OF FORMING AN AMORPHOUS SILICON LAYER ON A SUBSTRATE USING THE SAME

(71) Applicant: SAMSUNG ELECTRONICS CO., LTD., Suwon-si (KR)

(72) Inventors: SEUNG-HEON LEE, Seoul (KR); Koung-Min RYU, Hwaseong-si (KR); Kyung-Seok OH, Seoul (KR); Sang-Jin HYUN, Suwon-si (KR)

(21) Appl. No.: 16/052,063

(22) Filed: Aug. 1, 2018

(30) Foreign Application Priority Data
Sep. 25, 2017 (KR) 10-2017-0123782

(51) Int. Cl. H01L 21/033; H01L 29/66; H01L 21/3213; H01L 21/67; H01L 21/02; H01J 37/32; C23C 16/50; C23C 16/24

(52) U.S. Cl. CPC H01L 21/0337; H01L 29/66545; H01L 21/0332; H01L 21/32139; H01L 21/67213; H01L 21/02532; H01J 2237/3321; H01L 21/02664; H01L 21/67167; H01J 37/32715; C23C 16/50; C23C 16/24; H01L 21/0262

(57) ABSTRACT

Disclosed are an apparatus for forming a layer and a method of forming the layer using the same. The apparatus includes a transfer chamber in which a substrate is transferred, a deposition chamber positioned at a side of the transfer chamber and performing a deposition process on the substrate to thereby form the layer on the substrate, and at least a de-hydrogen chamber positioned at another side of the transfer chamber and performing a de-hydrogen process on the layer on the substrate to reduce a hydrogen concentration in the layer. Accordingly, the de-hydrogen process is performed in the apparatus without unloading of the substrate from the apparatus.

### CROSS-REFERENCE TO RELATED APPLICATIONS

This application claims priority under 35 U.S.C. § 119 to Korean Patent Application No. 10-2017-0123782, filed on Sep. 25, 2017, in the Korean Intellectual Property Office, the contents of which are incorporated by reference herein in their entirety.

### TECHNICAL FIELD

Example embodiments relate to an apparatus for forming a layer on a substrate and a method of forming a layer using the same, and more particularly, to an apparatus for forming a thin layer to which a low temperature deposition chamber and a de-hydrogen chamber are installed and a method of forming an amorphous silicon layer on a substrate using the same.

### DISCUSSION OF RELATED ART

Amorphous silicon layer has been widely used for manufacturing semiconductor devices. For example, the amorphous silicon layer may be used as a precursor for forming a polysilicon layer, or may be used as a dummy layer and/or a sacrificial layer in the manufacturing processes for the semiconductor devices. In addition, the amorphous silicon layer may also be used as a mask pattern for forming a pattern on a wafer.

In general, the amorphous silicon layer is usually formed on a substrate by low temperature deposition process such as a plasma-enhanced chemical vapor deposition (PECVD) process.

Since silane (SiH₄) gas or disilane (Si₂H₆) gas is usually used as a source gas for the conventional low temperature deposition process for forming the amorphous silicon layer, hydrogen (H) is obliged to be rich in the amorphous silicon layer. The hydrogen (H) in the amorphous silicon layer is discharged from the amorphous silicon layer as hydrogen bubbles in a subsequent process. The hydrogen bubble usually deteriorates the uniformity of the composition and/or the shape of the amorphous silicon layer, so the subsequent layer structure may have various defects that may be caused by the non-uniform composition and/or shape of the amorphous silicon layer. For that reason, the substrate on which the amorphous silicon layer has been formed is usually transferred to an additional annealing chamber and undergoes a de-hydrogen process for a relatively long time.

The transfer time between the annealing chamber and the deposition chamber and the process time of the de-hydrogen process may significantly deteriorate an overall manufacturing efficiency of the semiconductor devices. In addition, to individually install the de-hydrogen chamber apart from a deposition system for the amorphous silicon layer, the apparatuses for forming the amorphous silicon layer may require larger footprint and higher complexity.

As an aspect ratio tends to be relatively high in an etching process for forming a pattern due to the requirements of reducing critical dimension (CD) in semiconductor devices, a mask pattern for patterning an underlying layer may also tend to increase process defects due to the high aspect ratio. For that reason, a multi-step etching technique has been widely used in the process for forming the mask pattern for reducing the process defects. However, when a mask layer is formed in a multilayered structure in which the amorphous silicon layer and an etch stop layer are alternately stacked on an underlying layer, the inter-chamber transfer and the de-hydrogen process described above are required to every amorphous silicon layer. As a result, the process time for forming multilayered mask pattern may significantly increase and the overall efficiency for forming the mask pattern may be remarkably deteriorated.

### SUMMARY

Example embodiments of the present inventive concept provide an apparatus for forming a layer in which the low temperature deposition chamber and the de-hydrogen chamber are close to each other to increase the forming efficiency of a layer, and also provide a method of forming a thin layer on a substrate using the above apparatus.

According to an example embodiment of the present inventive concept, there is provided an apparatus including a load port on which a substrate holder is positioned, the substrate holder holding at least a substrate that is to be processed, a transfer chamber connected to the load port and transferring the substrate from the substrate holder, a deposition chamber positioned at a side of the transfer chamber and performing a deposition process on the substrate that is transferred from the transfer chamber by a transfer unit, thereby forming the layer on the substrate, and at least a de-hydrogen chamber positioned at another side of the transfer chamber and performing a de-hydrogen process on the layer on the substrate that is transferred from the transfer chamber by the transfer unit, thereby reducing a hydrogen concentration in the layer.

According to an example embodiment of the present inventive concept, there is provided a method of forming a thin layer on a substrate. The thin layer may be formed on the substrate in a deposition chamber that may be positioned at a side of a transfer chamber, and the substrate on which the thin layer may be formed may be loaded into a de-hydrogen chamber from the deposition chamber via the transfer chamber. The de-hydrogen chamber may be positioned at another side of the transfer chamber. A de-hydrogen process may be performed on the thin layer on the substrate in the de-hydrogen chamber, and the substrate on which the thin layer having a low hydrogen concentration may be formed may be transferred to a substrate holder from the de-hydrogen chamber via the transfer chamber.

According to an example embodiment of the present inventive concept, there is provided an apparatus including: a transfer chamber connected to a load port through a load lock chamber, in which a substrate is transferred from the load port via the load lock chamber to the transfer chamber; a deposition chamber positioned at a side of the transfer chamber and connected to the transfer chamber, in which the substrate is transferred from the transfer chamber to the deposition chamber for performing a deposition process on the substrate in the deposition chamber to form the layer on the substrate; and a de-hydrogen chamber positioned at another side of the transfer chamber and connected to the transfer chamber, in which the layer on the substrate is transferred from the deposition chamber to the de-hydrogen chamber via the transfer chamber for performing a de-hydrogen process on the layer on the substrate in the de-hydrogen chamber to reduce a hydrogen concentration in the layer.

### BRIEF DESCRIPTION OF THE DRAWINGS

These and other features of the present inventive concept will become more apparent by describing in detail exemplary embodiments thereof with reference to the accompanying drawings, in which:

FIG. 1 is a structural view illustrating an apparatus for forming a layer in accordance with an example embodiment of the present inventive concept;

FIG. 2 is a structural view illustrating a first modification of the apparatus for forming a layer shown in FIG. 1 in accordance with an example embodiment of the present inventive concept;

FIG. 3 is a structural view illustrating a second modification of the apparatus for forming a layer shown in FIG. 1 in accordance with an example embodiment of the present inventive concept;

FIG. 4 is a flow chart showing process steps for forming a thin layer on a substrate in the apparatus shown in FIG. 1 in accordance with an example embodiment of the present inventive concept; and

FIGS. 5A to 5F are cross-sectional views illustrating processing steps for a method of forming a replacement metal gate for a semiconductor device by using the method of forming a thin layer shown in FIG. 4 in accordance with an example embodiment of the present inventive concept.

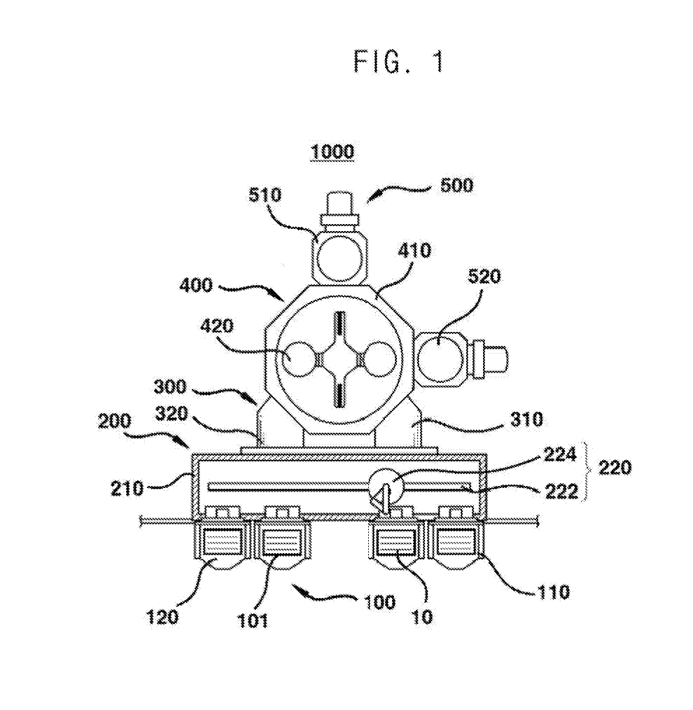

Since the drawings in FIGS. 1-3 and 5A-5F are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Reference will now be made to example embodiments of the present inventive concept, which are illustrated in the accompanying drawings, wherein like reference numerals may refer to like components throughout.

FIG. 1 is a structural view illustrating an apparatus for forming a layer in accordance with an example embodiment of the present inventive concept.

Referring to FIG. 1, an apparatus 1000 for forming a layer on a substrate in accordance with an example embodiment of the present inventive concept may include a load port 100 on which a substrate holder 101 may be positioned, a port selection module 200 for picking up a process substrate 10, which is to be processed, from the substrate holder 101 and stacking a processed substrate 10 into the substrate holder 101 on the load port 100, a load lock chamber 300, a transfer chamber 400 and a plurality of process chambers 500 arranged around the transfer chamber 400 and including at least a deposition chamber 510 for forming the layer on the process substrate 10 and at least a de-hydrogen chamber 520 for removing hydrogen from the layer on the process substrate 10.

In an example embodiment of the present inventive concept, the load port 100 may be positioned at a side of the port selection module 200 and may receive the substrate holder 101 in which a plurality of substrates 10 may be held. The substrate holder 101 may hold at least a substrate 10 that is to be processed or that has been processed. For example, the substrate holder 101 may include a wafer cassette or a front opening unified pod (FOUP). The FOUP is a non-removable wafer cassette in an enclosure. In the present example embodiment, the load port 100 may include a first port 110 in which the substrate 10 that is to be processed (hereinafter, referred to as process substrate) in the process chamber 500 and a second port 120 in which the substrate 10 that has been processed (hereinafter, referred to as processed substrate) in the process chamber 500.

The substrate 10 may include a bare substrate such as a bare silicon wafer or a bare glass substrate on which no layer is formed, or a substrate structure on which at least a layer structure has been formed. For example, the substrate structure may include a wafer structure on which various thin layers may be formed or a glass structure for a flat panel display device on which a thin film transistor (TFT) may be formed. The substrate 10 may be any suitable substrate and may include a semiconducting material, such as, for example, silicon (Si), germanium (Ge), silicon germanium (SiGe), silicon carbide (SiC), gallium nitride (GaN) or gallium arsenide (GaAs), a non-semiconducting material such as, for example, silicon oxide (SiO₂), aluminum (Al), aluminum oxide (Al₂O₃), ceramic, or quartz, or any combination thereof.

The port selection module 200 may pick up the process substrate 10 from the substrate holder 101 in the first port 110 and may transfer the selected process substrate 10 into the load lock chamber 300. In addition, the port selection module 200 may also receive the processed substrate 10 from the load lock chamber 300 and may transfer the processed substrate 10 into the substrate holder 101 in the second port 120.

The port selection module 200 may include a rectangular housing 210 having a predetermined volume, and a substrate selector 220 positioned in the rectangular housing 210 and moving along a longitudinal direction of the rectangular housing 210.

The load port 100 and the load lock chamber 300 may be arranged at long sides of the rectangular housing 210 opposite to each other. The substrate selector 220 may include a guide rail 222 extending along a longitudinal direction in parallel with the long side of the rectangular housing 210, and a robot arm 224 mounted on the guide rail 222 and moving along the longitudinal direction to thereby selectively face the first port 110 and the second port 120. Thus, the robot arm 224 may move along the guide rail 222 until the robot arm 224 faces the first port 110, then the process substrate 10 may be selected from the substrate holder 101 on the first port 110. The robot arm 224 may receive the processed substrate 10 from the load lock chamber 300 and may move along the guide rail 222 until the robot arm 224 faces the second port 120, then the processed substrate 10 may be stacked in the substrate holder 101 on the second port 120.

The robot arm 224 may be rotated on its own central axis. Thus, the robot arm 224 receiving the process substrate 10 selected from the first port 110 may move along the guide rail 222 to a gate of the load lock chamber 300 and may be rotated in such a way that the process substrate 10 in the robot arm 224 may be well inserted into the gate of the load lock chamber 300. In the same way, the robot arm 224 receiving the processed substrate 10 transferred from the load lock chamber 300 may move along the guide rail 222 to a gate of the substrate holder 101 on the second port 120, and may be rotated in such a way that the processed substrate 10 in the robot arm 224 may be well inserted into the gate of the substrate holder 101 on the second port 120.

The port selection module 200 may have various shapes and configurations according to the configurations of the load port 100, the load lock chamber 300 and the transfer chamber 400. The transfer chamber 400 may be connected to the load port 100 through the load lock chamber 300, in which the substrate 10 may be transferred from or to the load port 100 via the load lock chamber 300 to or from the transfer chamber 400. In other words, the transfer chamber 400 may be connected to the load port 100 and transferring the substrate 10 from or to the substrate holder 101.

The load lock chamber 300 may include an interface chamber for transferring the substrate 10 between the port selection module 200 and the transfer chamber 400. The port selection module 200 may be under room conditions and under a room temperature, and the load lock chamber 300 may be under transition conditions between the room conditions in the port selection module 200 and process conditions in the process chamber 500. Thus, the substrate 10 may be gradually transferred between the process conditions in the process chamber 500 and the room conditions in the port selection module 200 via the transition conditions in the load lock chamber 300, and the abrupt environmental shock to the substrate 10 may be sufficiently prevented by the load lock chamber 300.

In the present example embodiment, the load lock chamber 300 may include an inlet chamber 310 through which the process substrate 10 may be transferred from the first port 110 to the transfer chamber 400, and an outlet chamber 320 through which the processed substrate 10 may be transferred from the transfer chamber 400 to the second port 120.

The transfer chamber 400 may include a chamber shell 410 that may have various chamber areas corresponding to each of the process chambers 500, and a transfer unit 420 that may be positioned in the chamber shell 410 and may transfer the substrate 10 to one of the load lock chamber 300 and the process chambers 500.

The transfer chamber 400 may transfer the process substrate 10 to the process chamber 500 from the load lock chamber 300 and may transfer the processed substrate 10 to the load lock chamber 300 from the process chamber 500. That is, the substrate 10 may be transferred between the load lock chamber 300 and the process chamber 500 via the transfer chamber 400, and between the process chambers 500 via the transfer chamber 400.

The configurations and chamber conditions of the transfer chamber 400 may be varied according to the configurations of the process chamber 500 and the load lock chamber 300 and the mode of the substrate transfer.

When the substrate 10 is transferred between the load lock chamber 300 and the process chamber 500, the transfer chamber 400 may be controlled to have transition conditions between the process conditions of the process chamber 500 and the chamber conditions, which are also transition conditions and may or may not be different from the transition conditions of the transfer chamber 400, of the load lock chamber 300. In contrast, when the substrate 10 is transferred between the neighboring process chambers 500, the transfer chamber 400 may be controlled to have transition conditions between the process conditions of the neighboring process chambers 500.

A plurality of the process chambers 500 may be arranged around the transfer chamber 400, and the substrate 10 may be transferred from one process chamber to another process chamber via the transfer chamber 400 without being unloaded from the apparatus 1000. For example, the process chamber 500 may include at least a deposition chamber 510 for forming a thin layer on the substrate 10 and at least a de-hydrogen chamber 520 for performing the de-hydrogen process to remove hydrogen from the thin layer. A plurality of deposition chambers 510 and/or a plurality of the de-hydrogen chambers 520 may be arranged around the transfer chamber 400 according to the characteristics and requirements of the apparatus 1000.

The thin layer may be formed to include a plurality of hydrogen atoms in the deposition process, for example, in a low-temperature deposition process, and without performing the de-hydrogen process, various layer defects may occur in a subsequent process due to hydrogen bubbles. Example embodiments of the present inventive concept provide an apparatus for forming a thin layer in which the deposition chamber 510 and the de-hydrogen chamber 520 are close to each other to increase the forming efficiency of the thin layer. Thus, the present inventive concept may be applied to various thin layers as long as the layer defect due to the hydrogen bubbles may occur in a subsequent process after the formation of the thin layer. For example, the thin layer may include an amorphous silicon layer for semiconductor devices and/or thin layer transistors (TFT) of flat panel display devices.

In the present example embodiment, the deposition chamber 510 and the de-hydrogen chamber 520 may be arranged at first and second sides of the transfer chamber 400, so that the substrate 10 may be transferred between the deposition chamber 510 and the de-hydrogen chamber 520 without being unloaded from the apparatus 1000. Thus, the de-hydrogen process may be conducted in the apparatus 1000 and no additional de-hydrogen apparatus may be required for removing the hydrogen from the thin layer on the substrate 10. For example, the deposition chamber 510 may be positioned at a side, for example, the first side, of the transfer chamber 400 and connected to the transfer chamber 400, in which the substrate 10 may be transferred from the transfer chamber 400 to the deposition chamber 510 for performing the deposition process on the substrate 10 in the deposition chamber 510 to form the thin layer on the substrate 10, and the de-hydrogen chamber 520 may be positioned at another side, for example, the second side, of the transfer chamber 400 and connected to the transfer chamber 400, in which the thin layer on the substrate 10 may be transferred from the deposition chamber 510 to the de-hydrogen chamber 520 via the transfer chamber 400 for performing the de-hydrogen process on the thin layer on the substrate 10 in the de-hydrogen chamber 520 to reduce a hydrogen concentration in the thin layer. Since both the deposition chamber 510 and the de-hydrogen chamber 520 are close to and connected to the transfer chamber 400, the substrate 10 can be transferred freely and efficiently between the deposition chamber 510 and the de-hydrogen chamber 520 via the transfer chamber 400 without leaving the apparatus 1000.

When the thin layer is formed into a multilayered structure in which each component layer is separated from adjacent component layer by a separation layer, the de-hydrogen process to each component layer may be easily performed in the de-hydrogen chamber 520 just by transferring the substrate 10 having each component layer from the deposition chamber 510 via the transfer chamber 400. Thus, the de-hydrogen process to each component layer may be efficiently performed without any unloading of the substrate 10 having each component layer from the apparatus 1000.

The deposition chamber 510 may include a plasma-enhanced chemical vapor deposition (PECVD) chamber in which a PECVD process may be performed at a relatively low temperature.

The PECVD chamber may include a chuck structure for securing the substrate 10 and a shower head structure for supplying source gases for the PECVD process. The chuck structure may be positioned at a lower portion of the PECVD chamber and may move upwards and downwards in the PECVD chamber. The substrate 10 may be secured to an upper surface of the chuck structure. The shower head structure may be positioned at an upper portion of the PECVD chamber opposite to the chuck structure. Various electrodes may be arranged in the Chuck structure and may be connected to an external power source. Some of the electrodes in the chuck structure may heat the substrate 10 to a process temperature. The shower head structure may include a shower head for supplying the source gases for the PECVD process, and a base plate for securing the shower head to a ceiling of the PECVD chamber at a sufficient flat degree. The external power source may also be connected to the base plate.

In the present example embodiment, the source gases for the PECVD may include a mixture of silicon precursors and activation gases, thus the amorphous silicon layer may be formed on the substrate 10 by the PECVD process. Examples of the silicon precursors may include, for example, silane (SiH₄), disilane (Si₂H₆), dichlorosilane (SiH₂C1₂), and combinations thereof. Examples of the activation gases may include, for example, helium (He), neon (Ne), argon (Ar), krypton (Kr), and combinations thereof. Besides the inert gases described above, the activation gases may include other type of gases. For example, the activation gases may be a gas mixture which includes hydrogen gas (H₂) at a concentration of about 20% or less of the total gas mixture in combination with an inert gas as described above. Since one or more of silane (SiH₄), disilane (Si₂H₆) and dichlorosilane (SiH₂Cl₂) gases may be used as source gases for forming the amorphous silicon layer as described above, hydrogen (H) content may be high in the amorphous silicon layer.

The source gases may be supplied to the PECVD chamber, and an electric filed may be generated between the chuck structure and the shower head by the external power source having an impedance matching network and a radio frequency (RF) power. Thus, a plasma sheath may be generated between the chuck structure and the shower head and hydrogen atoms separated from the silicon precursors may be deposited to the substrate 10, which may be a silicon wafer, thereby forming an amorphous silicon layer bonded with hydrogen atoms on the substrate 10 in the PECVD chamber. A proper RF power may be used during the deposition process to ensure good uniformity of the deposited amorphous silicon layer.

In the present example embodiment, the PECVD process may be performed at a relatively low temperature, and the amorphous silicon layer may be formed to a thickness of about 40 nm to about 70 nm.

The low temperature of the PECVD process may be varied according to the requirements of the amorphous silicon layer. When the amorphous silicon layer is formed into a mask pattern on a dummy gate layer in a replace metal gate (RMG) process, the temperature of the PECVD process may be in a range of about 300° C. to about 500° C. When the temperature of the PECVD process is lower than about 300° C., the deposition time may excessively increase to thereby decrease an overall efficiency of the PECVD process for forming the amorphous silicon layer. In contrast, when the temperature of the PECVD process is over about 500° C., the dummy gate layer including polysilicon, which may be formed on the substrate 10 prior to the deposition process, may be rapidly crystallized and various process defects may be generated in the dummy gate layer. Therefore, when the amorphous silicon layer is formed on the dummy gate layer of the RMG process, the PECVD process may be performed at a temperature of about 300° C. to about 500° C.

When the amorphous silicon layer is formed to a thickness smaller than about 40 nm, the cost for the PECVD process may significantly increase for an excessively accurate control. In contrast, when the amorphous silicon layer is formed to a thickness over about 70 nm, the process time for the de-hydrogen process may excessively increase and the overall process time for forming the amorphous silicon layer may remarkably increase. Thus, the amorphous silicon layer may be formed into a thickness of about 40 nm to about 70 nm in view of the process efficiency for the deposition process and the de-hydrogen process.

The de-hydrogen chamber 520 may be positioned at a side of the transfer chamber 400, and the substrate 10 may be transferred between the deposition chamber 510 and the de-hydrogen chamber 520 via the transfer chamber 400.

The de-hydrogen chamber 520 may include an ultraviolet chamber in which an ultraviolet ray may be irradiated onto the thin layer on the substrate 10 at a room temperature to thereby break chemical bonds between hydrogen (H) and silicon (Si) in the thin layer, for example, the amorphous silicon layer.

The ultraviolet chamber may include a housing having an inner space, a chuck positioned at a lower portion of the housing and securing the substrate 10 having the thin layer, and an ultraviolet (UV) source positioned at an upper portion of the housing opposite to the chuck.

When the amorphous silicon layer is formed on the substrate 10 at the low temperature (hereinafter, referred to as low-temperature amorphous silicon layer), a quite amount of hydrogen atoms may be bonded to silicon atoms in the low-temperature amorphous silicon layer. Thus, the hydrogen atoms may be effusively blown off from the low-temperature amorphous silicon layer as hydrogen gases in a subsequent process. The effusively blown off hydrogen gases may be formed into hydrogen bubbles on a surface of the low-temperature amorphous silicon layer, and the hydrogen bubbles may cause various process defects in subsequent processes.

To prevent the hydrogen bubbles, when the thin layer is formed on the substrate 10 in the deposition chamber 510, the substrate 10 may be transferred to the de-hydrogen chamber 520 from the deposition chamber 510. In the present example embodiment, the substrate 10 having the amorphous silicon layer may be transferred to the UV chamber from the PECVD chamber. In the UV chamber, the hydrogen may be removed from the low-temperature amorphous silicon layer while minimizing the generation of the hydrogen bubbles on the surface of the low-temperature amorphous silicon layer. Particularly, the UV chamber may be under a temperature of about 10° C. to about 30° C. so as to efficiently prevent the generation of the hydrogen bubbles.

The transfer chamber 400 may be controlled to be under a transition temperature between the PECVD chamber and the UV chamber so as to minimize the temperature shock when the substrate 10 is transferred to the UV chamber under about 10° C. to about 30° C. from PECVD chamber under about 300° C. to about 500° C. In the present example embodiment, the transfer chamber 400 may be under a temperature of about 100° C. to about 150° C. The transfer time of the substrate 10 in the transfer chamber 400 may be controlled for minimizing the temperature shock to the substrate 10. The transition temperature of the transfer chamber 400 and the transfer time of the substrate in the transfer chamber 400 for minimizing the temperature shock to the substrate 10 may depend on the temperatures of the PECVD chamber and the UV chamber and the cooling rate of the substrate 10 in the transfer chamber 400.

The process conditions that may be common to the deposition chamber 510 and the de-hydrogen chamber 520 may be controlled to be unchanged in the transfer chamber 400. That is, the transfer chamber 400 may be controlled to have the process conditions the same as or very similar to the common conditions of the deposition chamber 510 and the de-hydrogen chamber 520, thereby minimizing the variation shock of the process conditions to the substrate 10 when the substrate 10 is transferred between the deposition chamber 510 and the de-hydrogen chamber 520 via the transfer chamber 400.

The ultraviolet rays may break the chemical bond between hydrogen (H) and silicon (Si) and may dissociate hydrogen from silicon in the low-temperature amorphous silicon layer, thereby decreasing the hydrogen density in the amorphous silicon layer. Particularly, since the dissociation of hydrogen from silicon may be performed at a room temperature in the UV chamber, the dissociated hydrogen may hardly be formed into the hydrogen bubbles. For example, the hydrogen (H) atom may be dissociated from silicon (Si) and may form hydrogen (H₂) gas, but the hydrogen (H₂) gas is not in the form of bubbles.

Since the thin layer may be formed into a thickness of about 40 nm to about 70 nm in the deposition chamber 510, the flow path of the dissociated hydrogen may be minimized in the thin layer and the dissociated hydrogen may be less likely to form the hydrogen bubbles in the thin layer.

In an example embodiment of the present inventive concept, the de-hydrogen chamber 520 may include a hydrogen plasma chamber in which a hydrogen plasma process may be performed on the thin layer on the substrate 10 and hydrogen atoms are separated from the thin layer as hydrogen gases.

The hydrogen plasma chamber may include a housing having a dosed inner space, a substrate support positioned at a lower portion of the housing and to which the substrate 10 may be secured, a shower head positioned at an upper portion of the housing and supplying the hydrogen gases into the housing, and a power source for applying an electrical power to the shower head and/or the substrate support and generating hydrogen plasma sheath on the substrate 10 in the hydrogen plasma chamber.

When the low-temperature thin layer having a relatively large quantity of hydrogen atoms is exposed to the hydrogen plasma sheath, the silicon-hydrogen bond in the thin layer may be broken and the dissociated hydrogen may be bonded to ions in the hydrogen plasma sheath to thereby form hydrogen gases.

The hydrogen plasma in the hydrogen plasma chamber may be formed at a temperature similar to that of the deposition chamber 510, so that the crystallization in an underlying layer under the thin layer may be minimized in the de-hydrogen process in the hydrogen plasma chamber. For example, the de-hydrogen process may be performed at a temperature of about 300° C. to about 500° C.

The transfer chamber 400 may be controlled to be under a transition temperature between temperatures of the deposition chamber 510 and the hydrogen plasma chamber, thereby minimizing the temperature shock to the substrate 10 when transferring the substrate 10 from the deposition chamber 510 to the hydrogen plasma chamber. For example, the transfer chamber 400 may be controlled to be under an average temperature of the deposition temperature in the deposition chamber 510 and the hydrogen plasma temperature in the hydrogen plasma chamber.

The transfer chamber 400 may also be controlled to have process conditions the same as or very similar to the common conditions of the deposition chamber 510 and the hydrogen plasma chamber, thereby minimizing the variation shock of the process conditions to the substrate 10 when the substrate 10 is transferred between the deposition chamber 510 and the hydrogen plasma chamber via the transfer chamber 400.

The de-hydrogen process in the hydrogen plasma chamber may be performed more rapidly than in the UV chamber, so that the thickness of the thin layer in the hydrogen plasma chamber may need to be smaller than in the UV chamber so as to minimize the hydrogen bubbles in the thin layer.

When the de-hydrogen process applied to the thin layer on the substrate 10 is completed, the substrate 10 may be unloaded from the de-hydrogen chamber 520 to the transfer chamber 400 and then may be transferred to the load lock chamber 300. Finally the substrate 10 having the de-hydrogenated thin layer may be transferred to the substrate holder 101 on the load port 100. In the present example embodiment, the substrate 10 may be transferred to the outlet chamber 320 and then may be stacked in the substrate holder 101 on the second port 120.

When the thin layer needs a thickness over about 70 nm, the deposition process and the de-hydrogen process may be repeated by repeatedly transferring the substrate 10 between the deposition chamber 510 and the de-hydrogen chamber 520.

When the de-hydrogen process performed on the thin layer is completed in the de-hydrogen chamber 520, the substrate 10 may be transferred again to the deposition chamber 510, not to the load lock chamber 300, from the de-hydrogen chamber 520. Thus, an additional thin layer may be further formed on the de-hydrogenated thin layer in the deposition chamber 510. In the present example embodiment, the additional thin layer may also be formed into a low-temperature layer having a relatively large quantity of hydrogen atoms. Thus, when the additional thin layer is formed on the de-hydrogenated thin layer in the deposition chamber 510, the substrate 10 may also be transferred to the de-hydrogen chamber 520 so as to remove the hydrogen from the additional thin layer.

The repetition of the deposition process and the de-hydrogen process may provide the thin layer having an expected thickness and a sufficiently low hydrogen density. In addition, a separation layer such as an etch stop layer may be further formed on the de-hydrogenated thin layer prior to the formation of the additional layer. In such a case, a multilayer, in which a number of component layers may each be separated from another by a separation layer interposed therebetween, may be formed on the substrate 10 by the repetition of the deposition process and the de-hydrogen process in the apparatus 1000.

The substrate 10 may be transferred to the de-hydrogen chamber 520 whenever each component layer is formed on the substrate 10, so that the de-hydrogen process may be performed on each component layer and may reduce the hydrogen amount in each component layer. Thus, an overall amount of the hydrogen may be sufficiently reduced in the multilayer.

Each de-hydrogen process to each component layer may be performed in the de-hydrogen chamber 520 that may be built in the apparatus 1000 without any additional de-hydrogen apparatus, thereby remarkably reducing cost and time for forming the de-hydrogenated multilayer on the substrate 10. According to the apparatus 1000 with which the deposition chamber 510 and the de-hydrogen chamber 520 may be equipped, the larger the number of the component layers in the multilayer, the greater the savings of the cost and time of the process for forming the multilayer in the apparatus 1000.

The configurations and structures of the de-hydrogen chamber 520 may be varied according to the installation requirements and operational characteristics of the apparatus 1000. For example, a plurality of the deposition chambers 510 and a plurality of the de-hydrogen chambers 520 may be arranged at the side of the transfer chamber 400, thereby increasing the throughput of the apparatus 1000 for forming the de-hydrogenated thin layer.

In an example embodiment of the present inventive concept, a single deposition chamber 510 and various de-hydrogen chambers 520 may be arranged at the side of the transfer chamber 400, thereby performing an optimal de-hydrogen process in view of the thin layer and reducing the process time of the de-hydrogen time in the apparatus 1000.

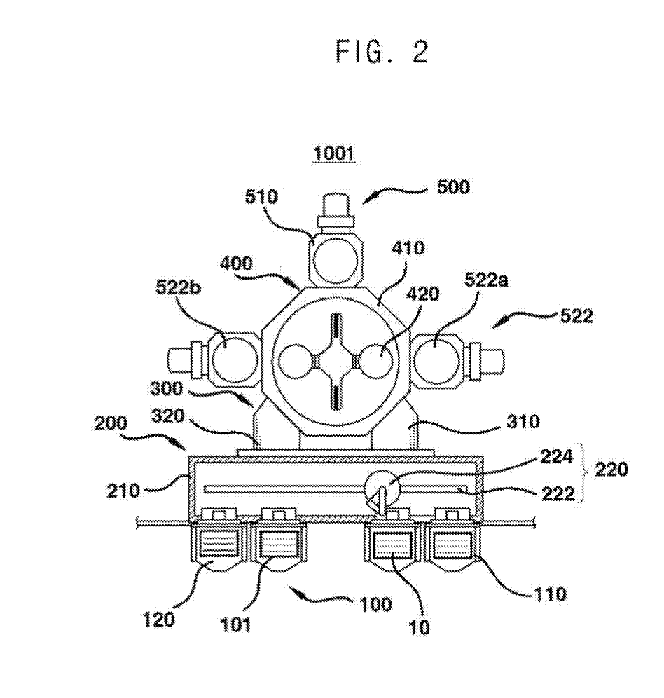

FIG. 2 is a structural view illustrating a first modification of the apparatus for forming a layer shown in FIG. 1 in accordance with an example embodiment of the present inventive concept. In FIG. 2, the first modified apparatus 1001 may have a structure substantially the same as that of the apparatus 1000 shown in FIG. 1, except that a pair of different de-hydrogen units are arranged at the side of transfer chamber 400, respectively. Thus, in FIG. 2, the same reference numerals denote the same elements in FIG. 1 and any further detailed descriptions on the same elements will be omitted hereinafter.

Referring to FIG. 2, the first modified apparatus 1001 may include a first modified de-hydrogen chamber 522 having a first de-hydrogen unit 522a and a second de-hydrogen unit 522b each as an individual chamber.

In the present example embodiment, the first de-hydrogen unit 522a may include a UV chamber in which an ultraviolet ray may be irradiated onto the thin layer on the substrate 10 at a room temperature to thereby break chemical bonds between hydrogen (H) and silicon (Si) in the thin layer, and the second de-hydrogen unit 522b may include a hydrogen plasma chamber in which a hydrogen plasma process may be performed on the thin layer on the substrate 10 and hydrogen atoms may be separated from the thin layer as hydrogen gases.

The UV chamber and the hydrogen plasma chamber may have structures substantially the same as those of the UV chamber and the hydrogen plasma chamber as described in detail with reference to FIG. 1, respectively. The first de-hydrogen unit 522a may be positioned at a first side of the transfer chamber 400 and the second de-hydrogen unit 522b may be positioned at a second side of the transfer chamber 400. The substrate 10 may be transferred between the first and the second de-hydrogen units 522a and 522b via the transfer chamber 400. That is, the deposition chamber 510 and the first and the second de-hydrogen units 522a and 522b may be arranged around the same transfer chamber 400 in the apparatus 1000.

While the de-hydrogen process in the UV chamber may need a relatively large process time, the de-hydrogen process in the hydrogen plasma chamber may be likely to generate the hydrogen bubbles in the thin layer in spite of the relatively short process time. Thus, the substrate 10 having the thin layer may be transferred at first to the first de-hydrogen unit 522a for breaking or weakening the hydrogen-silicon bond in the thin layer, and then may be transferred to the second de-hydrogen unit 522b from the first de-hydrogen unit 522a for rapidly removing the hydrogen from the thin layer. Accordingly, the de-hydrogen process may be performed on the thin layer in a shorter time without the hydrogen bubbles.

While the present example embodiment discloses that the UV chamber may be provided as the first de-hydrogen unit 522a and the hydrogen plasma chamber may be provided as the second de-hydrogen unit 522b, but the present inventive concept is not limited thereto. For example, various de-hydrogen apparatus/equipments may be provided as the first and the second de-hydrogen units 522a and 522b as long as the variation shock of the process conditions is minimized to the substrate 10 and the substrate transfer between the first and the second de-hydrogen units 522a and 522b is sufficiently facilitated in the transfer chamber 400. In addition, three or more de-hydrogen units may also be arranged at the side of the transfer chamber 400.

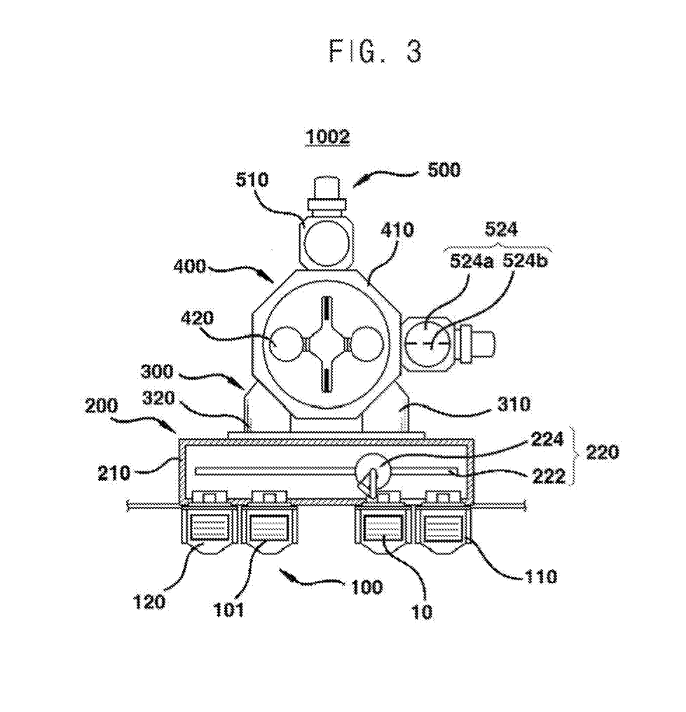

FIG. 3 is a structural view illustrating a second modification of the apparatus for forming a layer shown in FIG. 1 in accordance with an example embodiment of the present inventive concept. In FIG. 3, the second modified apparatus 1002 may have a structure substantially the same as that of the apparatus 1000 shown in FIG. 1, except that a pair of different de-hydrogen units are arranged as a single chamber at the side of transfer chamber 400. Thus, in FIG. 3, the same reference numerals denote the same elements in FIG. 1 and any further detailed descriptions on the same elements will be omitted hereinafter.

Referring to FIG. 3, the second modified apparatus 1002 may include a second modified de-hydrogen chamber 524 having a first de-hydrogen unit 524a and a second de-hydrogen unit 524b in a single chamber. That is, the second modified de-hydrogen chamber 524 may include a single composite chamber structure in which different de-hydrogen processes may be performed at the same time or sequentially. For example, the ultraviolet process and the hydrogen plasma process may be performed on the thin layer on the substrate 10 in a single chamber at the same time or sequentially.

The second modified de-hydrogen chamber 524 may include a single chamber of which the inner space may be divided into a pair of separated spaces by a separation wall. Then, first and second de-hydrogen units 524a and 524b may be provided with the separation spaces, respectively in the single chamber. In the present example embodiment, the first de-hydrogen unit 524a may perform the de-hydrogen process by using the ultraviolet rays and the second de-hydrogen unit 524b may perform the de-hydrogen process under the hydrogen plasma state. For example, the second modified de-hydrogen chamber 524 may include the first de-hydrogen unit 524a as an ultraviolet section in which an ultraviolet ray is irradiated onto the thin layer on the substrate 10 at a room temperature to thereby break chemical bonds between hydrogen and silicon in the thin layer, and the second de-hydrogen unit 524b as a hydrogen plasma section in which a hydrogen plasma process is performed on the thin layer on the substrate 10 and hydrogen atoms are separated from the thin layer as hydrogen gases. Accordingly, the de-hydrogen process under the ultraviolet rays and the de-hydrogen process under the hydrogen plasma state may be sequentially performed in the same chamber without passing through the transfer chamber 400. Therefore, the process time for de-hydrogenating from the thin layer may be significantly reduced and the overall time for forming the de-hydrogenated thin layer may decrease in the second modified apparatus 1002.

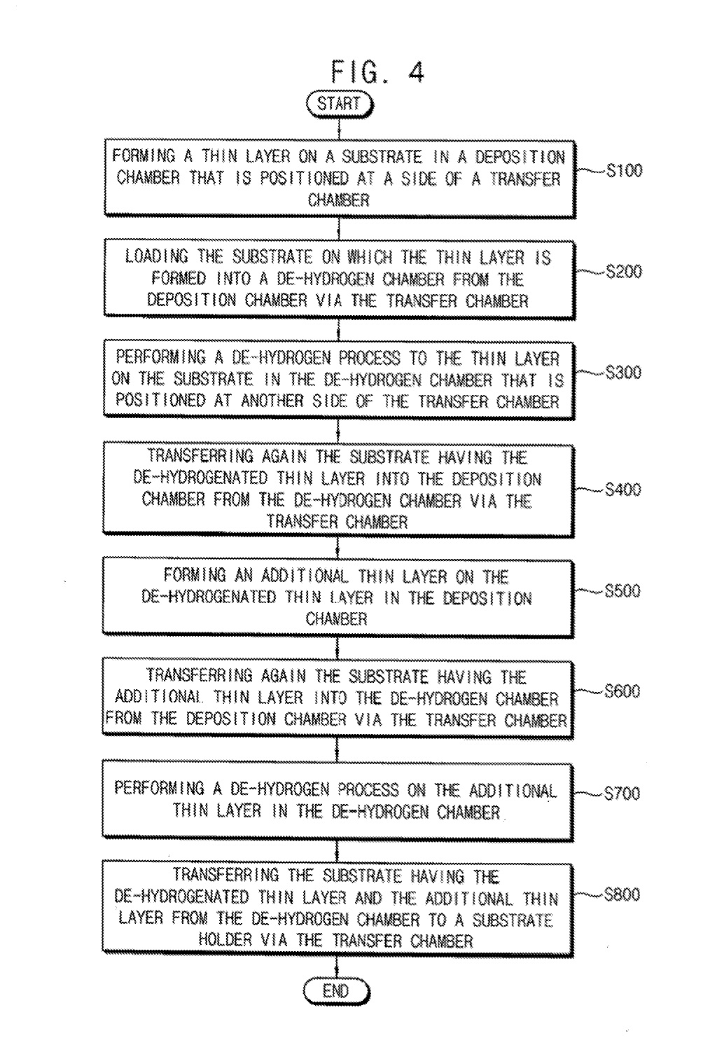

FIG. 4 is a flow chart showing process steps for forming a thin layer on a substrate 10 in the apparatus shown in FIG. 1 in accordance with an example embodiment of the present inventive concept.

Referring to FIGS. 1 and 4, the thin layer may be formed on the substrate 10 in the deposition chamber 510 that may be positioned at a first side of the transfer chamber 400 (step S100).

The substrate 10 may include a bare silicon wafer or a substrate structure having a layer structure on a bare substrate, and a plurality of the substrates 10 may be stacked in the substrate holder 101. The substrate holder 101 may be transferred onto the first port 110 from a prior apparatus by an inter-apparatus transfer system such as, for example, an overhead hoist transport (OHT). Then, the process substrate 10 may be picked up and selected from the substrates 10 in the substrate holder 101 by the port selection module 200 and the process substrate 10 may be loaded into the transfer chamber 400 via the load lock chamber 300.

The transfer chamber 400 may be under the transition conditions between the process conditions of the deposition chamber 510 and the transition conditions of the load lock chamber 300, so the variation shock or damage to the substrate 10 caused by the chamber conditions may be minimized when the substrate 10 is loaded into the deposition chamber 510 from the load lock chamber 300 via the transfer chamber 400.

In the present example embodiment, the substrate 10 may be secured to the chuck in the deposition chamber 510, and the PECVD process may be performed on the substrate 10 in the deposition chamber 510. The temperature of the substrate 10 may be controlled in a range of about 300° C. to about 500° C., and the source gases may be supplied into the deposition chamber 510 through the shower head.

The source gases may include a mixture of the silicon precursors including at least one of, for example, silane (SiH₄), disilane (Si₂H₆) and dichlorosilane (SiH₂Cl₂), and the activation gases for activating the silicon precursors into plasma state. Examples of the activation gases may include, for example, helium (He), neon (Ne), argon (Ar), krypton (Kr), and combinations thereof. Besides the inert gases described above, the activation gases may include other type of gases. For example, the activation gases may be a gas mixture which includes hydrogen gas (H₂) at a concentration of about 20% or less of the total gas mixture in combination with an inert gas as described above.

An amorphous silicon layer may be formed to a thickness of about 40 nm to about 70 nm on the substrate 10 as the thin layer by the PECVD process in the deposition chamber 510. Since the amorphous silicon layer may be formed at a relatively low temperature in the PECVD process, a relatively large amount of hydrogen atoms may be bonded to silicon atoms in the amorphous silicon layer. Thus, applying the de-hydrogen process to the amorphous silicon layer may be required for reducing the hydrogen density.

After the thin layer being formed on the substrate 10, the substrate 10 having the thin layer may be transferred to the de-hydrogen chamber 520 via the transfer chamber 400 (step S200).

After completing the deposition process on the substrate 10 in the deposition chamber 510, the gate of the deposition chamber 510 may be opened and the substrate 10 having the thin layer may be unloaded from the deposition chamber 510 to the transfer chamber 400. Then, the substrate 10 may be moved toward the de-hydrogen chamber 520 by the transfer unit 420 for a predetermined transfer time in the transfer chamber 400, and then may be loaded into the de-hydrogen chamber 520.

Prior to the unloading of the substrate 10 from the deposition chamber 510, the transfer chamber 400 may be controlled to be under transition conditions between the deposition conditions in the deposition chamber 510 and the de-hydrogen conditions in the de-hydrogen chamber 520, thereby minimizing the substrate damage caused by the environmental changes or the process condition changes between the deposition chamber 510 and the de-hydrogen chamber 520.

The transfer time of the substrate 10 in the transfer chamber 400 may be optimized for minimizing the substrate damage caused by the process condition changes. Thus, transfer time of the substrate 10 may be greater than a minimal transfer time of the transfer unit 420 which may be generally specified by a manufacturer of the transfer chamber 400.

Conventionally, the substrate having the thin layer was unloaded from the apparatus for forming the thin layer and then was loaded again into an additional de-hydrogen apparatus for reducing the hydrogen density in the thin layer. However, according to the present example embodiments of the apparatus 1000, the substrate 10 having the thin layer may be transferred to the de-hydrogen chamber 520 from the deposition chamber 510 via the transfer chamber 400 without any unloading of the substrate 10 from the apparatus 1000. Therefore, the process efficiency of the de-hydrogen process may be significantly enhanced in the apparatus 1000.

After the substrate 10 having the thin layer being transferred to the de-hydrogen chamber 520, the de-hydrogen process may be performed on the thin layer on the substrate 10 in the de-hydrogen chamber 520 (step S300).

A UV irradiation process and/or a hydrogen plasma process may be performed in the de-hydrogen chamber 520. The UV irradiation process may be performed at a temperature of about 10° C. to about 30° C. and the hydrogen plasma process may be performed at a temperature that may be less than or equal to the temperature of the deposition process.

The hydrogen-silicon bond in the thin layer may be broken by the UV rays under the room temperature and thus the hydrogen density in the thin layer may decrease by the UV irradiation process. In addition, the hydrogen in the thin layer may react with ions of the hydrogen plasma much more actively than with silicon in the thin layer, so that the hydrogen in the thin layer may be turned into hydrogen gases by the hydrogen plasma to thereby decrease the hydrogen density in the thin layer.

Since the UV irradiation process may be performed under the room temperature, the dissociated hydrogen may hardly be formed into the hydrogen bubbles when the dissociated hydrogen is discharged from the thin layer.

Since the thin layer may be formed to a thickness of about 40 nm to about 70 nm, the flow path of the dissociated hydrogen may be minimized in the thin layer and the dissociated hydrogen may be less likely to form the hydrogen bubbles in the thin layer. Therefore, the surface non-uniformity of the thin layer caused by the hydrogen bubbles may be sufficiently minimized in the apparatus 1000.

The de-hydrogen process may be variously performed according to the configurations of the de-hydrogen chamber 520.

The UV irradiation or the hydrogen plasma process may be individually performed on the thin layer. Otherwise, both the UV irradiation process and the hydrogen plasma process may be continuously performed on the thin layer. Particularly, the hydrogen plasma process sequentially performed after the UV irradiation process in the same apparatus may sufficiently reduce the de-hydrogen process time as compared to when the UV irradiation process or the hydrogen plasma process is individually performed.

Since the UV irradiation process may be performed under a room temperature, the de-hydrogen process may require a relatively large amount of process time, which may increase an overall process time for forming the de-hydrogenated thin layer.

The hydrogen plasma process may remove the hydrogen atoms from the thin layer in a relatively short time due to the high reactivity of the hydrogen in the thin layer with the ions of the hydrogen plasma. However, since the hydrogen plasma process may be performed at a temperature relatively high as compared to that of the UV irradiation process, the dissociated hydrogen may likely be formed into the hydrogen bubbles, which may cause the non-uniformity of the surface profile and the compositions of the thin layer. Therefore, the sequential performance of the UV irradiation process and the hydrogen plasma process may decrease the overall process time for forming the de-hydrogenated thin layer.

The UV chamber and the hydrogen plasma chamber may each be individually arranged at a different side of the transfer chamber 400, and the substrate 10 having the thin layer may be sequentially transferred to the UV chamber and the hydrogen plasma chamber from the deposition chamber 510. Thus, the substrate 10 having the thin layer may be transferred at first to the UV chamber for breaking or weakening the hydrogen-silicon bond in the thin layer, and then may be transferred to the hydrogen plasma chamber from the UV chamber for rapidly removing the hydrogen from the thin layer.

The UV irradiation process and the hydrogen plasma process may be performed in a single chamber. As shown in FIG. 3, a UV irradiation unit and a hydrogen plasma unit may be provided with the single chamber and the UV irradiation process and the hydrogen plasma process may be sequentially performed in the same chamber. Accordingly, the de-hydrogen process may be performed on the thin layer in a shorter time without the hydrogen bubbles.

After the de-hydrogen process, the substrate 10 having the de-hydrogenated thin layer may be unloaded from the de-hydrogen chamber 520 to the transfer chamber 400 and then may be stacked in the substrate holder 101 on the second port 120 via load lock chamber 300 and the port selection module 200.

In case that the multilayer is required on the substrate 10, the substrate 10 having the de-hydrogenated thin layer may be transferred again into the deposition chamber 510 from the de-hydrogen chamber 520 via the transfer chamber 400 (step S400). Then, the additional thin layer may be formed on the de-hydrogenated thin layer in the deposition chamber 510 (step S500). Particularly, the additional thin layer may be separated from the de-hydrogenated thin layer by a separation layer such as an etch stop layer, thereby forming the multilayer on the substrate 10.

The additional thin layer may be formed by the same low temperature deposition process used in forming the thin layer in the same deposition chamber 510, so the substrate 10 having the additional thin layer may also be transferred again to the de-hydrogen chamber 520 from the deposition chamber 510 via the transfer chamber 400 (step S600) and the de-hydrogen process may be performed on the additional thin layer in the de-hydrogen chamber 520 (step S700).

The de-hydrogen process may be individually performed to both of the thin layer and the additional thin layer in the apparatus 1000, so that the hydrogen density of the multilayer may sufficiently decrease in the apparatus 1000.

When the multilayer includes a plurality of component layers, each of the plurality of component layers may be separated from the neighboring one by the respective separation layer, and the deposition process and the de-hydrogen process may be alternately repeated in the apparatus 1000. In such a case, the substrate 10 may be transferred to the de-hydrogen chamber 520 whenever each component layer is formed on the substrate 10, thus the de-hydrogen process may be performed on each component layer, and as a result, the hydrogen density in each component layer may be sufficiently reduced. Thus, an overall amount of the hydrogen may be sufficiently reduced even in the multilayer.

According to the conventional apparatus for forming a thin layer in which the de-hydrogen process was performed by an additional de-hydrogen equipment, the substrate 10 was usually unloaded from the apparatus whenever each component layer underwent the de-hydrogen process and then was loaded again into the apparatus for forming another component layer, which requires a great amount of time for the de-hydrogen process. However, in an example embodiment of the present inventive concept, according to the apparatus 1000 with which the deposition chamber 510 and the de-hydrogen chamber 520 may be equipped, the de-hydrogen process to each component layer may be performed in the de-hydrogen chamber 520 that may be built in the apparatus 1000 without any additional de-hydrogen apparatus, thereby remarkably reducing cost and time for forming the de-hydrogenated multilayer on the substrate 10.

As described above, the hydrogen amount may be efficiently reduced even in the multilayer in the apparatus 1000 with which the deposition chamber 510 and the de-hydrogen chamber 520 may be equipped. Particularly, the larger the number of the component layers in the multilayer, the greater the savings of the cost and time of the process for forming the multilayer in the apparatus 1000.

When the de-hydrogen process is completed in the de-hydrogen chamber 520, the substrate 10 may be unloaded from the de-hydrogen chamber 520 to the transfer chamber 400. Then, the substrate 10 may be further transferred to the substrate holder 101 via the load lock chamber 300 and the port selection module 200 (step S800).

According to the apparatus for forming a thin layer and the method of forming the thin layer on the substrate in an example embodiment of the present inventive concept, the transfer chamber 400 for transferring the substrate 10 may be provided with the apparatus, and the deposition chamber 510 for forming the thin layer at a relatively low temperature and the de-hydrogen chamber 520 may be arranged at the side of the transfer chamber 400. Thus, the de-hydrogen process for decreasing the hydrogen density in the thin layer may be performed in the same apparatus just by transferring between the deposition chamber 510 and the de-hydrogen chamber 520 via the transfer chamber 400, thereby reducing the process time of the de-hydrogen process and increasing the reliability of the de-hydrogen process.

The de-hydrogen process may be performed by a sequential process of the UV irradiation process and the hydrogen plasma process. Since the UV irradiation process may be performed at a room temperature, the hydrogen bubbles may hardly be generated during the de-hydrogen process. The hydrogen plasma process may remove the hydrogen atoms from the thin layer in a relatively short time due to the high reactivity of the hydrogen in the thin layer with the ions of the hydrogen plasma. Therefore, the sequential performance of the UV irradiation process and the hydrogen plasma process may decrease the overall process time for forming the de-hydrogenated thin layer without the hydrogen bubbles.

When the thin layer includes an amorphous silicon layer that may be formed by a PECVD process under a relatively low temperature and thus a relatively large amount of hydrogen atoms may be bonded with silicon atoms in the amorphous silicon layer, the hydrogen density of the amorphous silicon layer may be sufficiently reduced just by the substrate transfer between the deposition chamber 510 and the de-hydrogen chamber 520 in the apparatus. Accordingly, the hydrogen bubbles may hardly be generated from the amorphous silicon layer in a subsequent process and the process defects caused by the hydrogen bubbles may be minimized in a subsequent process.

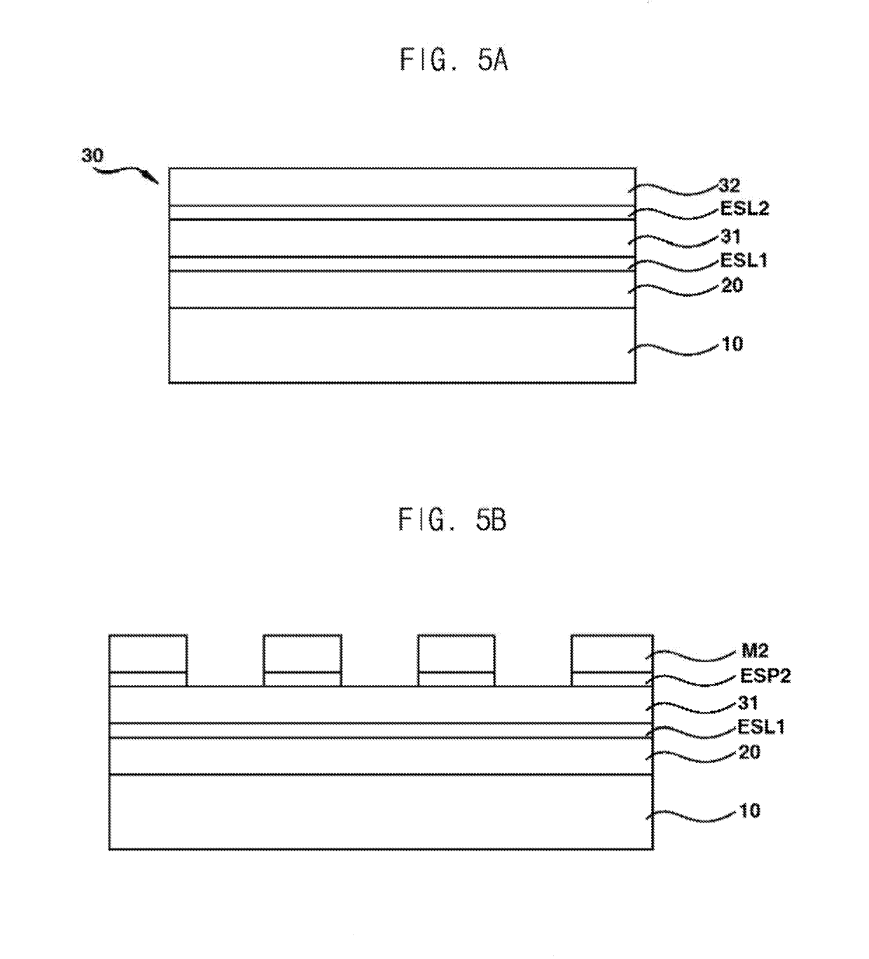

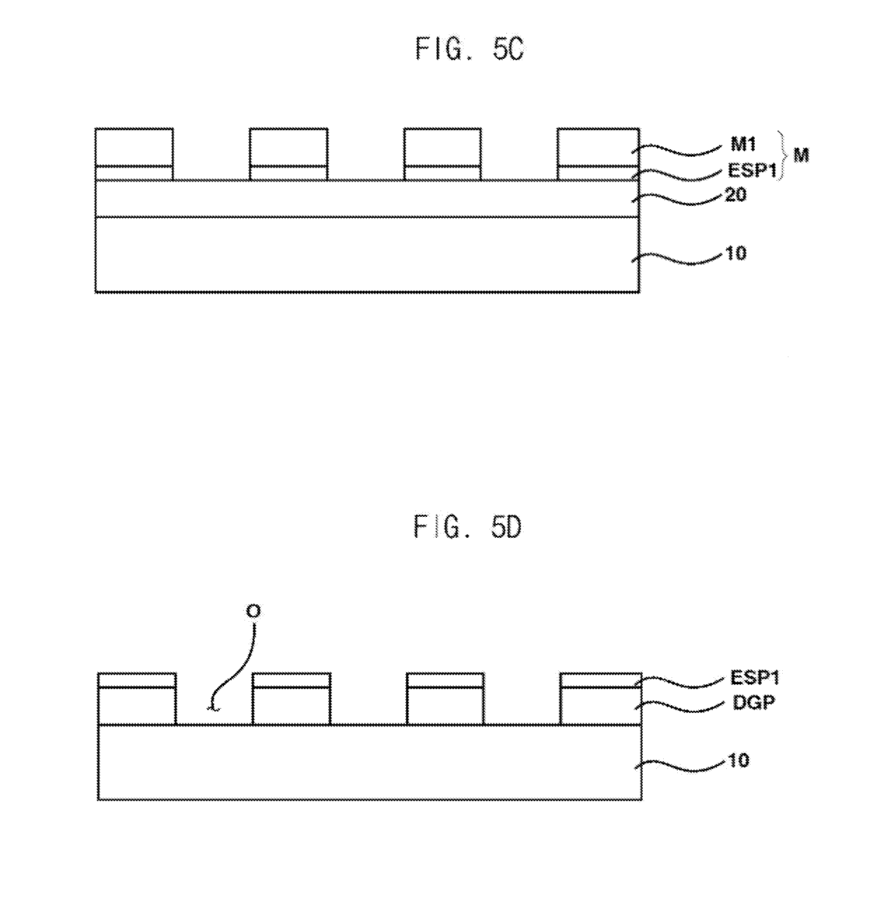

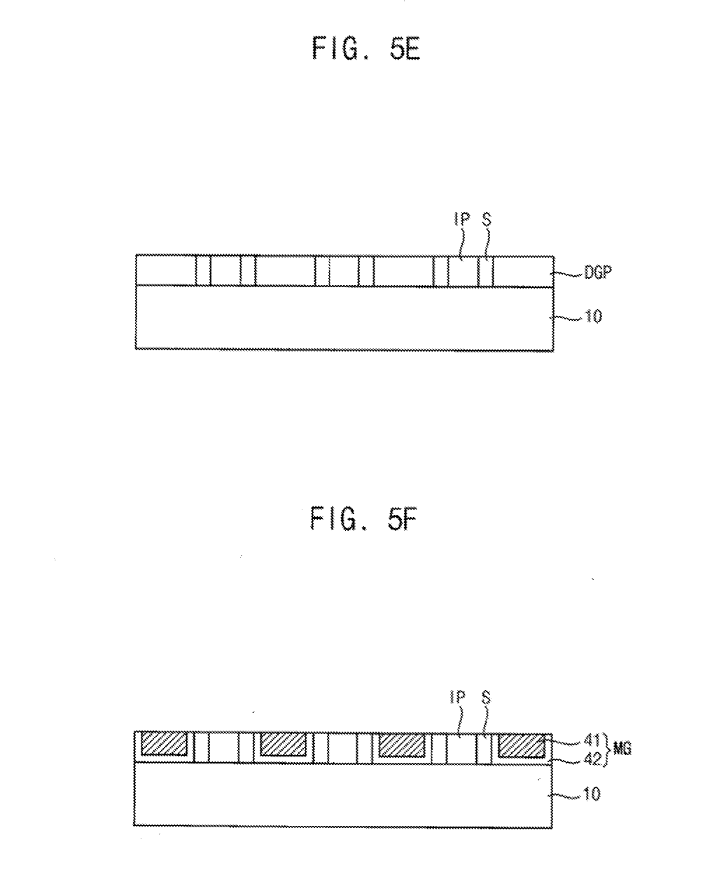

FIGS. 5A to 5F are cross-sectional views illustrating processing steps for a method of forming a replacement metal gate for a semiconductor device by using the method of forming a thin layer shown in FIG. 4 in accordance with an example embodiment of the present inventive concept.

Referring to FIGS. 1, 4 and 5A, a dummy gate layer 20 and a plurality of mask layers 30 may be formed on the substrate 10. The dummy gate layer 20 and the mask layers 30 may be separated from one another by an etch stop layer ESL. The mask layer 30 may include amorphous silicon.

The dummy gate layer 20 may be formed on the substrate 10 by a deposition process in the deposition chamber 510. The substrate 10 may be loaded into the deposition chamber 510, and a proper deposition process for forming the dummy gate layer 20 may be performed on the substrate 10. Various deposition processes such as, for example, a chemical vapor deposition (CVD) process and an atomic layer deposition (ALD) process may be performed in the deposition chamber 510.

The dummy gate layer may be formed on the substrate 10 in a prior process before loading the substrate 10 into the apparatus 1000. In such a case, the substrate 10 on which the dummy gate layer 20 may be formed may be loaded into the apparatus 1000.

A first etch stop layer ESL1 and a first mask layer 31 may be sequentially formed on the dummy gate layer 20 in the deposition chamber 510.

The first etch stop layer ESL1 may be formed on the dummy gate layer 20 by a proper deposition process and then the chamber conditions of the deposition chamber 510 may be changed for a low-temperature plasma enhanced chemical vapor deposition (PECVD) process. Then, the low-temperature PECVD process may be performed on the substrate 10 in the deposition chamber 510.

The substrate 10 may be controlled in a temperature range of about 300° C. to about 500° C. and the silicon precursors and the activation gases may be supplied into the deposition chamber 510 through the shower head as source gases for the PECVD process. Thus, the first mask layer 31 including amorphous silicon may be formed on the first etch stop layer ESL1 by the PECVD process.

The first mask layer 31 may be formed at a relatively low temperature, and a relatively large amount of hydrogen atoms may be bonded to silicon atoms in the first mask layer 31.

The substrate 10 having the first mask layer 31 may be transferred to the de-hydrogen chamber 520 from the deposition chamber 510 via the transfer chamber 400. Thus, the de-hydrogen process may be performed on the first mask layer 31 in the de-hydrogen chamber 520.

After completing the de-hydrogen process on the first mask layer 31, the substrate 10 may be transferred again to the deposition chamber 510 from the de-hydrogen chamber 520. Then, the second etch stop layer ESL2 and the second mask layer 32 may be sequentially formed on the first mask layer 31 in a way the same as that of the first etch stop layer ESL1 and the first mask layer 31 being formed. Then, the substrate 10 may be transferred again to the de-hydrogen chamber 520 and the de-hydrogen process may be performed on the second mask layer 32. Therefore, the first and the second mask layers 31 and 32 of which the hydrogen density may be sufficiently reduced may be formed on the substrate 10.

The de-hydrogen process may be individually performed to each of the first and the second mask layers 31 and 32 just by transferring the substrate 10 between the deposition chamber 510 and the de-hydrogen chamber 520 via the transfer chamber 400, thereby efficiently reducing the hydrogen density in each of the first and the second mask layers 31 and 32.

As a result of the process described above, the hydrogen bubbles may hardly be generated in a subsequent patterning process to the first and the second mask layers 31 and 32. The hydrogen bubbles may deteriorate the surface profile and compositions of the first and the second mask layers 31 and 32. Thus, the less hydrogen bubbles in the patterning process to the first and the second mask layers 31 and 32 may enhance the quality and reliability of the mask pattern.

While the present example embodiment discloses the first and the second mask layers 31 and 32 may be formed on the substrate 10, one or more additional mask layers may be further formed on the second mask layer 32 according to the requirements of the replacement metal gate process.

Referring to FIGS. 1, 4 and 5B, the second mask layer 32 and the second etch stop layer ESL2 may be patterned into a second mask pattern M2 and a second etch stop pattern ESP2 through which the first mask layer 31 may be partially exposed.

A photoresist pattern may be formed on the second mask layer 32 and a photolithography process may be performed on the second mask layer 32 using the photoresist pattern as a mask pattern, thereby forming the second mask pattern M2. Thereafter, the second etch stop layer ESL2 may be partially removed by an etching process using the second mask pattern M2 as an etching mask.

Since the hydrogen may be sufficiently removed from the second mask layer 32 by the de-hydrogen process, the hydrogen bubbles may hardly be generated from the second mask layer 32 in the photolithography process and the etching process. Thus, the surface profile and composition of the second mask layer 32 may be sufficiently uniform in the photolithography process and the etching process.

Referring to FIGS. 1, 4 and 5C, the first mask layer 31 and the first etch stop layer ESL1 may be patterned into a first mask pattern M1 and a first etch stop pattern ESP1 through which the dummy gate layer 20 may be partially exposed.

An etching process may be performed on the first mask layer 31 and the first etch stop layer ESL1 using the second mask pattern M2 and the second etch stop pattern ESP2 as an etching mask, thereby forming the first mask pattern M1 and the first etch stop pattern ESP1.

The second mask pattern M2 may be removed from the substrate 10 in the etching process to the first mask layer 31, and the second etch stop pattern ESP2 may be removed from the substrate 10 in the etching process to the first etch stop layer ESL1. Thus, only the first mask pattern M1 and the first etch stop pattern ESP1 may be formed on the dummy gate layer 20. That is, a mask pattern M having the first mask pattern M1 and the first etch stop pattern ESP1 may be formed on the dummy gate layer 20.

Since the hydrogen may be sufficiently removed from the first mask layer 31 by the de-hydrogen process, the hydrogen bubbles may hardly be generated in the etching process for forming the first mask pattern M1 and the first etch stop pattern ESP1. Thus, the surface profile and composition of the first mask layer 31 may be sufficiently uniform in the etching process. That is, the surface profile and composition of the mask pattern M may be uniform along the whole substrate 10.

Since the mask pattern M may be formed on the dummy gate layer 20 by a double patterning process using the second mask pattern M2, the pattern configurations of the photoresist pattern may be accurately transcribed onto the mask pattern M.

Since the hydrogen density may be sufficiently reduced in the first and the second mask layers 31 and 32 and the surface profiles and compositions of the first and the second mask layers 31 and 32 may be kept being uniform in the patterning process for forming the mask pattern M, the pattern accuracy of the mask pattern M may be much more enhanced. Accordingly, the dummy gate layer 20 may be accurately patterned by using the mask pattern M even when the critical dimension (CD) of the replacement metal gate may be less than about 10 nm.

Referring to FIGS. 1, 4 and 5D, the dummy gate layer 20 may be patterned into a dummy gate pattern DGP by an etching process using the mask pattern M as an etching mask. The dummy gate pattern DGP may have an opening O through which the substrate 10 may be partially exposed.

Since the dummy gate layer 20 may include polysilicon and the first mask pattern M1 may include amorphous silicon, the first mask pattern M1 may be removed from the substrate 10 in the etching process for patterning the dummy gate layer 20. Therefore, only the first etch stop pattern ESP1 may remain on the dummy gate pattern DGP after the etching process.

Referring to FIGS. 1, 4 and 5E, a gate spacer S may be formed on sidewalls of the opening O and then the opening O may be filled up with an insulation pattern IP.

A spacer layer including insulation materials may be conformally formed on the substrate 10 along a surface profile of the dummy gate pattern DGP and then may be patterned into the gate spacer S by an anisotropic etching process.

After forming the gate spacer S, an insulation layer may be formed on the substrate 10 to a sufficient thickness to fill up the opening O that may be defined by the gate spacer S, and then may be planarized, for example, by a chemical mechanical planarization (CMP) process or an etch hack process, until a top surface of the dummy gate pattern DGP is exposed, thereby forming the insulation pattern IP in the opening O.

Referring to FIGS. 1, 4 and 5F, the dummy gate pattern DGP may be removed from the substrate 10 and a gate hole that may be defined by a pair of the gate spacers S may be formed on the substrate 10. Then, a gate insulation layer may be formed on the substrate 10 along a surface profile of the gate hole. A conductive metal layer may be formed on the gate insulation layer to a sufficient thickness to fill up the gate hole that may be defined by the gate insulation layer. Thereafter, the conductive metal layer and the gate insulation layer may be planarized, for example, by a CMP process or an etch back process, until a top surface of the gate spacer S is exposed, thereby forming a replace metal gate MG having a gate insulation pattern 42 and a metal pattern 41 in the gate hole.

According to the method of forming the replacement metal gate in an example embodiment of the present inventive concept, the mask layer may be formed into a multilayer having the first and the second mask layers 31 and 32 and the hydrogen density of the multilayer may be sufficiently reduced in the apparatus. Thus, the surface profiles and compositions of the multilayered mask layer may be kept being uniform in the double patterning process for forming the mask pattern M, so that the pattern accuracy of the mask pattern M may be significantly enhanced. Accordingly, the dummy gate layer may be accurately patterned by using the mask pattern M even when the critical dimension (CD) of the replacement metal gate is less than about 10 nm.

The apparatus for forming a thin layer and a method of forming thin layer using the same in accordance with an example embodiment of the present inventive concept, the transfer chamber 400 for transferring the substrate 10 may be provided with the apparatus, and the deposition chamber 510 for forming the thin layer at a relatively low temperature and the de-hydrogen chamber 520 for reducing the hydrogen density in the thin layer may be arranged at the side of the transfer chamber 400. Thus, the de-hydrogen process for decreasing the hydrogen density in the thin layer may be performed in the same apparatus just by transferring between the deposition chamber 510 and the de-hydrogen chamber 520 via the transfer chamber 400, thereby reducing the process time of the de-hydrogen process and increasing the reliability of the de-hydrogen process.

The de-hydrogen process may be performed by a sequential process of the UV irradiation process and the hydrogen plasma process. Since the UV irradiation process may be performed at a room temperature, the hydrogen bubbles may hardly be generated during the de-hydrogen process. The hydrogen plasma process may remove the hydrogen atoms from the thin layer in a relatively short time due to the high reactivity of the hydrogen in the thin layer with the ions of the hydrogen plasma. Therefore, the sequential performance of the UV irradiation process and the hydrogen plasma process may decrease the overall process time for forming the de-hydrogenated thin layer without the hydrogen bubbles.

When the thin layer includes an amorphous silicon layer that may be formed by a PECVD process under a relatively low temperature, and thus a relatively large amount of hydrogen atoms may be bonded with silicon atoms in the amorphous silicon layer, the hydrogen density of the amorphous silicon layer may be sufficiently reduced just by the substrate transfer between the deposition chamber 510 and the de-hydrogen chamber 520 in the apparatus. Accordingly, the hydrogen bubbles may hardly be generated from the amorphous silicon layer in a subsequent process, and the process defects caused by the hydrogen bubbles may be minimized in a subsequent process.

The foregoing is illustrative of example embodiments of the present inventive concept and is not to be construed as limiting thereof. Although a few specific example embodiments have been described, those skilled in the art will readily appreciate that many modifications are possible in the example embodiments without materially departing from the spirit and scope of the present inventive concept as defined by the appended claims.

What is claimed is:

1. An apparatus for forming a layer comprising:
a load port on which a substrate holder is positioned, the substrate holder holding at least a substrate that is to be processed;
a transfer chamber connected to the load port and transferring the substrate from or to the substrate holder;
a deposition chamber positioned at a side of the transfer chamber and performing a deposition process on the substrate that is transferred from the transfer chamber by a transfer unit, thereby forming the layer on the substrate; and
at least a de-hydrogen chamber positioned at another side of the transfer chamber and performing a de-hydrogen process on the layer on the substrate that is transferred from the transfer chamber by the transfer unit, thereby reducing a hydrogen concentration in the layer.

2. The apparatus of claim 1, wherein the deposition chamber comprises a plasma-enhanced chemical vapor deposition (PECVD) chamber in which the deposition process is performed at a relatively low temperature.

3. The apparatus of claim 2, wherein the layer comprises an amorphous silicon layer that is formed on the substrate in the PECVD chamber by a PECVD process using a mixture of precursors having silicon and activation gases as source gases.

4. The apparatus of claim 2, wherein the relatively low temperature is in a range of about 300° C. to about 500° C.

5. The apparatus of claim 1, wherein the de-hydrogen chamber comprises an ultraviolet chamber in which an ultraviolet ray is irradiated onto the layer on the substrate at a room temperature to thereby break chemical bonds between hydrogen and silicon in the layer.

6. The apparatus of claim 5, wherein the room temperature is in a range of about 10° C. to about 30° C.

7. The apparatus of claim 1, wherein the de-hydrogen chamber comprises a hydrogen plasma chamber in which a hydrogen plasma process is performed on the layer on the substrate, and hydrogen atoms are separated from the layer as hydrogen gases.

8. The apparatus of claim 1, wherein the de-hydrogen chamber comprises an ultraviolet section in which an ultraviolet ray is irradiated onto the layer on the substrate at a room temperature to thereby break chemical bonds between hydrogen and silicon in the layer, and a hydrogen plasma section in which a hydrogen plasma process is performed on the layer on the substrate and hydrogen atoms are separated from the layer as hydrogen gases.

9. A method of forming a layer on a substrate comprising:
forming a thin layer on the substrate in a deposition chamber that is positioned at a side of a transfer chamber;
loading the substrate on which the thin layer is formed into a de-hydrogen chamber from the deposition chamber via the transfer chamber, the de-hydrogen chamber being positioned at another side of the transfer chamber;
performing a de-hydrogen process on the thin layer on the substrate in the de-hydrogen chamber; and
transferring the substrate on Which the thin layer having a low hydrogen concentration is formed to a substrate holder from the de-hydrogen chamber via the transfer chamber.

10. The method of claim 9, wherein the thin layer is formed into an amorphous silicon layer by a plasma enhanced chemical vapor deposition (PECVD) process using a mixture of silicon precursors and activation gases as source gases, the silicon precursors comprising at least one of silane (SiH₄), disilane (Si₂H₆) and dichlorosilane (SiH₂Cl₂), and the activation gases comprising at least one of helium (He), neon (Ne), argon (Ar) and krypton (Kr).

11. The method of claim 10, wherein the de-hydrogen process is performed by at least one of an ultraviolet process in which an ultraviolet ray is irradiated onto the thin layer on the substrate to thereby break chemical bonds between hydrogen and silicon in the thin layer, and a hydrogen plasma process in which the hydrogen plasma process is performed on the thin layer on the substrate and hydrogen atoms are separated from the thin layer as hydrogen gases.

12. The method of claim 11, wherein the ultraviolet process is performed at a temperature of about 10° C. to about 30° C.

13. The method of claim 11, wherein the ultraviolet process and the hydrogen plasma process are performed in a single chamber.

14. The method of claim 11, wherein the ultraviolet process and the hydrogen plasma process are each performed at a respective chamber that is positioned individually at a different side of the transfer chamber.

15. The method of claim 9, after performing the de-hydrogen process on the thin layer on the substrate, further comprising:
transferring again the substrate on which the thin layer having the low hydrogen concentration is formed into the deposition chamber from the de-hydrogen chamber via the transfer chamber;
forming an additional thin layer on the thin layer having the low hydrogen concentration in the deposition chamber;
transferring again the substrate having the additional thin layer into the de-hydrogen chamber from the deposition chamber via the transfer chamber; and
performing the de-hydrogen process on the additional thin layer in the de-hydrogen chamber.

16. An apparatus for forming a layer comprising:
a transfer chamber connected to a load port through a load lock chamber, wherein a substrate is transferred from the load port via the load lock chamber to the transfer chamber;
a deposition chamber positioned at a side of the transfer chamber and connected to the transfer chamber, wherein the substrate is transferred from the transfer chamber to the deposition chamber for performing a deposition process on the substrate in the deposition chamber to form the layer on the substrate; and
a de-hydrogen chamber positioned at another side of the transfer chamber and connected to the transfer chamber, wherein the layer on the substrate is transferred from the deposition chamber to the de-hydrogen chamber via the transfer chamber for performing a de-hydrogen process on the layer on the substrate in the de-hydrogen chamber to reduce a hydrogen concentration in the layer.

17. The apparatus of claim 16, wherein the layer is an amorphous silicon layer formed by a plasma enhanced chemical vapor deposition (PECVD) process in the deposition chamber using a mixture of silicon precursors comprising at least one of silane (SiH₄), disilane (Si₂H₆) and dichlorosilane (SiH₂Cl₂), and activation gases comprising at least one of helium (He), neon (Ne), argon (Ar) and krypton (Kr).

18. The apparatus of claim 17, wherein the amorphous silicon layer is formed to a thickness of about 40 nm to about 70 nm.

19. The apparatus of claim 16, wherein the de-hydrogen chamber comprises at least one of an ultraviolet chamber in Which an ultraviolet ray is irradiated onto the layer on the substrate at a room temperature to thereby break chemical bonds between hydrogen and silicon in the layer, and a hydrogen plasma chamber in which a hydrogen plasma process is performed on the layer on the substrate, and hydrogen atoms are separated from the layer as hydrogen gases.

20. The apparatus of claim 16, wherein the de-hydrogen chamber comprises an ultraviolet section in which an ultraviolet ray is irradiated onto the layer on the substrate at a room temperature to thereby break chemical bonds between hydrogen and silicon in the layer, and a hydrogen plasma section in which a hydrogen plasma process is performed on the layer on the substrate and hydrogen atoms are separated from the layer as hydrogen gases.
